(19) United States
(12) Patent Application Publication
(10) Pub. No.: US 2015/0009615 A1
(43) Pub. Date: Jan. 8, 2015

(54) PAD STRUCTURE AND PRINTED CIRCUIT BOARD AND MEMORY STORAGE DEVICE USING THE SAME

(71) Applicant: Phison Electronics Corp., Miaoli (TW)

(72) Inventors: Chih-Jen Hsu, Hsinchu County (TW); Chun-Feng Lee, Hsinchu City (TW)

(73) Assignee: Phison Electronics Corp., Miaoli (TW)

(21) Appl. No.: 14/056,958

(22) Filed: Oct. 18, 2013

(30) Foreign Application Priority Data
Jul. 5, 2013 (TW) 102124206

(51) Int. Cl. H05K 1/11; G06F 1/18

(52) U.S. Cl. CPC H05K 1/111; G06F 1/18
USPC 361/679.31; 174/261

(57) ABSTRACT

A pad structure for disposing an electronic component on a printed circuit board is provided. The pad structure includes a first pad and a plurality of second pads. The first pad is configured to couple to a terminal of the electronic component. Each of the second pads is configured to couple to another terminal of the electronic component. The first pad and the second pads are electrically independent to each other, and the second pads are electrically independent to each other. Besides, a printed circuit board and a memory storage device using the pad structure are also provided.

### CROSS-REFERENCE TO RELATED APPLICATION

This application claims the priority benefit of Taiwan application serial no. 102124206, filed on Jul. 5, 2013. The entirety of the above-mentioned patent application is hereby incorporated by reference herein and made a part of this specification.

### BACKGROUND

1. Technology Field

The invention relates to a circuit layout, and more particularly, to a pad structure, and a printed circuit board and a memory storage device using the same.

2. Description of Related Art

With advancement of technologies for manufacturing printed circuit boards (PCB) and electronic components, in order to meet the demands for miniaturized electronic products, the printed circuit boards and the electronic components are tended to be designed with small sizes. However, reduction of a size of a printed circuit board results in difficulties of a layout design for the printed circuit board.

Generally, in the layout design for the printed circuit board, a pad structure matching a size of an electronic component is usually utilized for coupling the electronic component to other components/circuits on the printed circuit board. In the pad structure of conventional art, only one single pad is commonly used to couple a terminal of the electronic component. For instance, when the electronic component is an electronic component with two terminals, the pad structure is usually designed to include two pads for coupling to the terminals of the electronic component, respectively.

However, since a conventional pad structure can only establish one single connection node for coupling to the other circuits on the printed circuit board, thus, in some layout designs for the printed circuit board, additional electronic components (e.g., a resistor with low resistance) are often added so that two different circuits can be coupled to each other, and a pad structure and a wiring for the additional electronic component are also required as a connection path between the two different circuit. Accordingly, an overall layout area of the printed circuit board may be increased so as to increase a layout density of the printed circuit board, such that difficulty in the circuit layout design is also significantly increased.

Nothing herein should be construed as an admission of knowledge in the prior art of any portion of the present invention. Furthermore, citation or identification of any document in this application is not an admission that such document is available as prior art to the present invention, or that any reference forms a part of the common general knowledge in the art.

### SUMMARY

The exemplary embodiments of the invention are directed to a pad structure, and a printed circuit board and a memory storage device using the same, which are capable of reducing a layout area in a circuitry design.

A pad structure according to an exemplary embodiment of the invention is configured for disposing an electronic component on a printed circuit board. The pad structure includes a first pad and a plurality of second pads. The first pad is configured to couple to a terminal of the electronic component. Each of the second pads is configured to couple to another terminal of the electronic component, wherein the first pad and the second pads are electrically independent to each other, and the second pads are electrically independent to each other.

The exemplary embodiment of the invention provides a printed circuit board including at least a first pad structure. Each first pad structure includes a first pad and a plurality of second pads. The first pad is configured to couple to a terminal of an electronic component. Each of the second pads is configured to couple to another terminal of the electronic component, wherein the first pad and the second pads are electrically independent to each other, and the second pads are electrically independent to each other.

From another perspective, a memory storage device is provided according to an exemplary embodiment of the invention, and the memory storage device includes a connector, a rewritable non-volatile memory module and a memory controller. The connector is configured to couple to a host system. The rewritable non-volatile memory module includes a plurality of physical erasing units. The memory controller is coupled to the connector and the rewritable non-volatile memory. The connector or the memory controller is disposed on a printed circuit board, and the printed circuit board includes at least one first pad structure. Each first pad structure includes a first pad and a plurality of second pads. The first pad is configured to couple to a terminal of an electronic component. Each of the second pads is configured to couple to another terminal of the electronic component, wherein the first pad and the second pads are electrically independent to each other, and the second pads are electrically independent to each other.

In summary, in the exemplary embodiments of the invention, a pad structure, and a printed circuit board and a memory storage device using the same are provided. The pad structure includes at least two pads configured for coupling to the same terminal of the electronic component, so as to establish an additional connection node for the electronic component. Accordingly, the designer can directly utilize the additional connection node to connect two different circuits, so as to reduce the layout area of the circuitry design for the printed circuit board, and improve commonality and flexibility for the circuit layout design.

It should be understood, however, that this Summary may not contain all of the aspects and embodiments of the present invention, is not meant to be limiting or restrictive in any manner, and that the invention as disclosed herein is and will be understood by those of ordinary skill in the art to encompass obvious improvements and modifications thereto.

To make the above features and advantages of the disclosure more comprehensible, several embodiments accompanied with drawings are described in detail as follows.

### BRIEF DESCRIPTION OF THE DRAWINGS

FIG. 1 is a schematic diagram illustrating a pad structure and an electronic component according to an exemplary embodiment.

FIG. 2A is a schematic diagram of a printed circuit board and a layout structure thereof.

FIG. 2B is a schematic diagram of an equivalent circuit of the printed circuit board depicted in FIG. 2A.

FIG. 3A is a schematic diagram illustrating a printed circuit board and a layout structure thereof according to an exemplary embodiment.

FIG. 3B is a schematic diagram of an equivalent circuit of the printed circuit board depicted in FIG. 3A.

FIG. 4A illustrates a host system and a memory storage device according to an exemplary embodiment.

FIG. 4B is a schematic diagram illustrating a computer, an input/output device and a memory storage device according to an exemplary embodiment.

FIG. 4C is a schematic diagram of a host system and a memory storage device according to an exemplary embodiment.

FIG. 5 is a schematic block diagram of the memory storage device depicted in FIG. 4A.

### DESCRIPTION OF THE EMBODIMENTS

In order to make content of the present disclosure more comprehensible, exemplary embodiments are described below as the examples to prove that the present disclosure can actually be realized. However, the invention is not limited to the exemplary embodiments illustrated herein, and a proper combination between the embodiments can also be made. Moreover, elements/components/steps with same reference numerals represent same or similar parts in the drawings and embodiments.

Embodiments of the present invention may comprise any one or more of the novel features described herein, including in the Detailed Description, and/or shown in the drawings. As used herein, “at least one”, “one or more”, and “and/or” are open-ended expressions that are both conjunctive and disjunctive in operation. For example, each of the expressions “at least on of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together.

It is to be noted that the term “a” or “an” entity refers to one or more of that entity. As such, the terms “a” (or “an”), “one or more” and “at least one” can be used interchangeably herein.

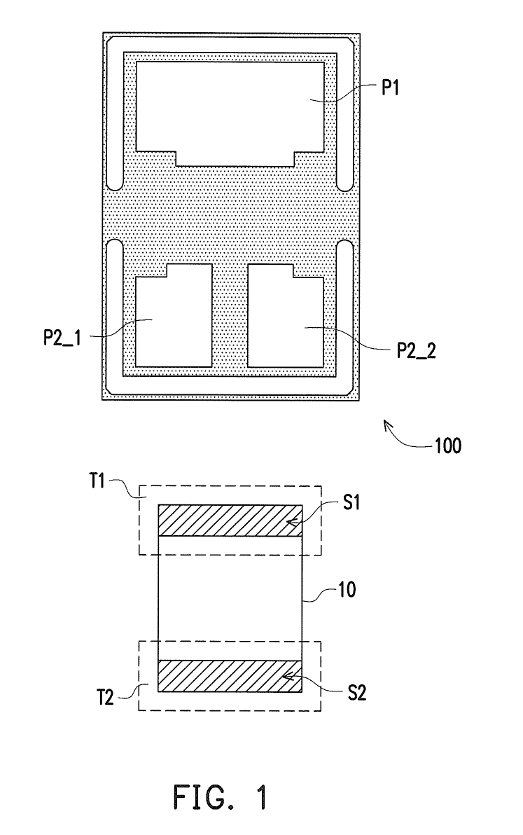

FIG. 1 is a schematic diagram illustrating a pad structure and an electronic component according to an exemplary embodiment. Referring to FIG. 1, in the present exemplary embodiment, a pad structure 100 is configured for disposing an electronic component 10 on a printed circuit board, so that the electronic component 10 can be coupled to other components/circuits on the printed circuit board through the pad structure 100, so that the electronic component 10 can realize corresponding functions in circuitry. Herein, the electronic component 10 may be an active component or a passive component, and the invention is not limited thereto. For instance, the electronic component 10 may be a metal-oxide-semiconductor field-effect transistor (MOSFET), a bipolar junction transistor (BJT), a capacitor, a resistor or an inductor. In such exemplary embodiment, the pad structure 100 is used in the electronic component 10 with two terminals. The pad structure 100 includes a first pad P1 and second pads P2_1 and P2_2. The first pad P1 is configured to couple to a first terminal T1 of the electronic component 10, and the second pads P2_1 and P2_2 are configured to couple to a second terminal T2 of the electronic component 10, wherein the first pad P1 and the second pads P2_1 and P2_2 are electrically independent to each other, and the second pads P2_1 and P2_2 are also electrically independent to each other.

In an exemplary embodiment, the electronic component 10 is a surface mounting device (SMD) having solder junctions S1 and S2. If a designer intends to dispose the electronic component 10 on the printed circuit board (not illustrated) through the pad structure 100, the designer can solder the solder junction S1 onto the first pad P1 and solder the solder junction S2 onto the second pads P2_1 and P2_2. In other words, in the pad structure 100, the first pad P1 is coupled to the first terminal T1 of the electronic component 10 through the solder junction S1, and the second pads P2_1 and P2_2 are coupled to the second terminal T2 of the electronic component 10 through the solder junction S2. Under such configuration of soldering the electronic component 10 in the pad structure 100, the second pads P2_1 and P2_2 are electrically connected to each other through the solder junction S2 of the electronic component 10.

In the present exemplary embodiment, the second pads P2_1 and P2_2 are disposed on a side of the pad structure 100 according to a position of the second terminal T2 of the electronic component 10, and the first pad P1 is disposed on another side and opposite to the second pads P2_1 and P2_2 according to a position of the first terminal T1 of the electronic component 10, but the invention is not limited thereto. In another exemplary embodiment, positions and amounts of the pads can be configured differently according to positions and amounts of terminals/pins/junctions of the electronic component 10, such that the electronic component 10 can be disposed on the printed circuit board through the pad structure 100.

For instance, in case the electronic component 10 is a surface mounting device with three terminals, besides the first pad P1 and the second pads P2_1 and P2_2, the designer can also dispose a third pad (not illustrated) in the pad structure 100 according to a position of a solder junction of a third terminal of the electronic component 10. Accordingly, the third terminal of the electronic component 10 can be coupled to other components/circuits on the printed circuit board through the third pad. In other words, in such exemplary embodiment, the pad structure 100 further includes the third pad configured to couple to the third terminal of the electronic component. In particular, the first pad P1 and the second pad P2_1, the second pad P2_2 and the third pad are electrically independent to each other. Nevertheless, in case the electronic component 10 includes more terminals, the pad structure 100 can also include more pads, accordingly.

Further, it is illustrated in FIG. 1 that the second pads P2_1 and P2_2 are coupled to the second terminal T2 of the electronic component 10. However, in another exemplary embodiment, the designer can also design more than three second pads in the pad structure 100, and said second pads are all coupled to the same terminal (e.g., the second terminal T2) of the electronic component 10, so as to provide more than three connection nodes.

Accordingly, in the pad structure of the present exemplary embodiment, the positions and amounts of the pads can be adaptively adjusted according to types of the electronic component being applied (e.g., two terminals, three terminals or more than three terminals), and the invention is not thereby limited. In other words, it does not depart from the scope of pad structure in the invention for which protection is sought, as along as more than two pads are configured for coupling to the same terminal of the electronic component in the same pad structure, and said more than two pads are electrically independent to each other when not being coupled to the electronic component.

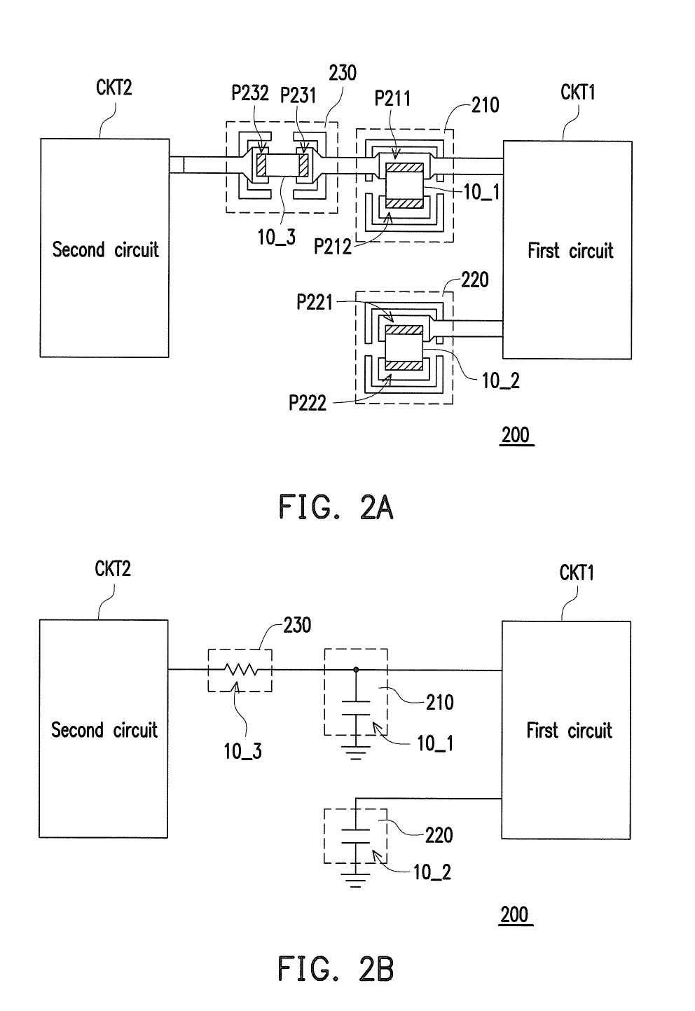

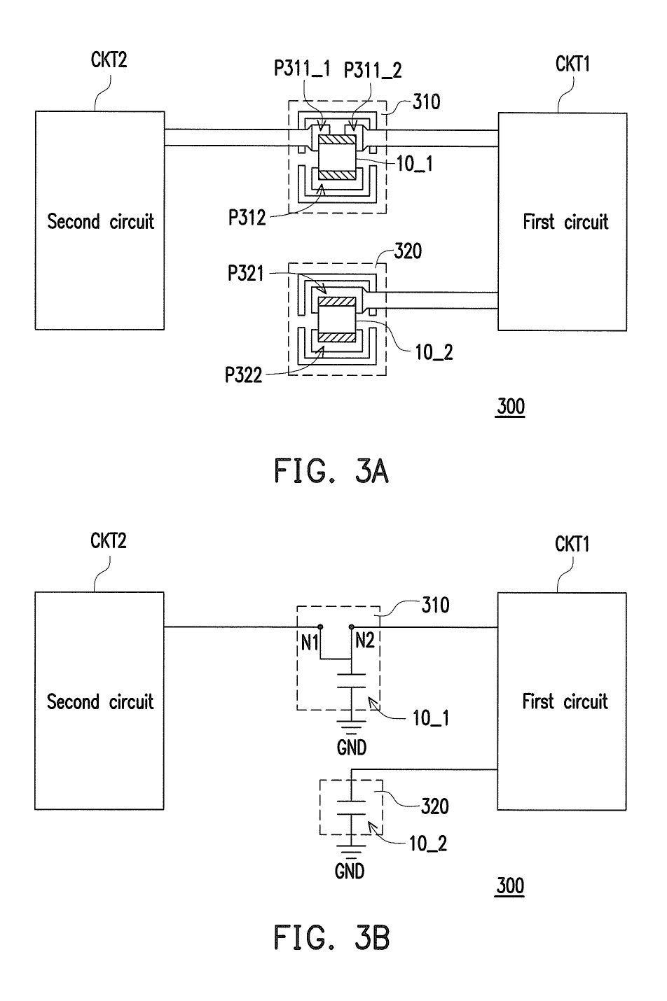

A difference between the pad structure 100 of the present exemplary embodiment and a conventional pad structure, when being used in the layout design of the printed circuit board, is described below with references to FIGS. 2A to 3B.

FIG. 2A is a schematic diagram of a printed circuit board and a layout structure thereof. FIG. 2B is a schematic diagram of an equivalent circuit of the printed circuit board depicted in FIG. 2A. Referring to FIGS. 2A and 2B together, a printed circuit board 200 includes a first circuit CKT1, a second circuit CKT2, a plurality of pad structures 210, 220 and 230, and electronic components 10_1 to 10_3. Therein, the printed circuit board 200 can be used in any type of electronic device.

The pad structures 210, 220 and 230 are the conventional pad structures, where each one utilizes two pads for coupling to an electronic component. For instance, a pad P211 and a pad P212 are coupled to two terminals of the electronic component 10_1; a pad P221 and a pad P222 are coupled to two terminals of the of the electronic component 10_2; and a pad P231 and a pad P232 are coupled to two terminals of the electronic component 10_3. Therein, before the electronic component 10_3 is disposed on the electronic component 230, the pad 231 and the pad 232 are electrically independent to each other. Herein, the electronic components 10_1 and 10_2 are, for example, a capacitor, and the electronic component 10_1 is, for example, a resistor.

More specifically, in the printed circuit board 200, the first circuit CKT1 is a primary function circuit (i.e., a circuit required for the printed circuit board 200 to operate normally), and the second circuit CKT2 is an auxiliary function circuit (i.e. a circuit to provide additional functions, and the designer can decide whether to add this circuit). The designer can decide whether to add the second circuit CKT2 according to a specification requirement of the electronic device that uses the printed circuit board 200, and thereby designing a corresponding layout structure for the printed circuit board 200.

For instance, the first circuit CKT1 is a controller circuit, and the second circuit CKT2 is an external power-supply circuit configured to provide an external power. In case the designer intends to design the electronic device to work by utilizing an internal power of the first circuit CKT1, the designer does not need to consider the layout structure from the second circuit CKT2 to the first circuit CKT1. Otherwise, in case the designer intends to design the electronic device to work by utilizing the external power, the designer needs to design the corresponding layout structure for the printed circuit board, so that the second circuit CKT2 can be coupled to the first circuit CKT1.

More specifically, in an implementation without the second circuit CKT2, the designer only needs to consider disposition of the pad structures 210 and 220, and the wirings from the electronic components 10_1 and 10_2 to the first circuit CKT1, in order to complete the layout design for the printed circuit board 200. On the contrary, in an implementation with the second circuit CKT2, the designer needs to further design a wiring layout for the second circuit CKT2 to be coupled to the first circuit CKT1. Under such implementation, since the printed circuit board 200 uses the conventional pad structure 230, the designer needs to dispose an additional resistor 10_3 and a wiring thereof as a connection path between the second circuit CKT2 and the first circuit CKT2.

In view of above, it can be known that in the design of the layout structure for the printed circuit board using the conventional pad structure, the designer needs to design two different layout structures for the printed circuit board with respect to the electronic devices with different specification. Moreover, in the implementation with the second circuit CKT2, additional layout area for the pad structure 230 is required on the printed circuit board 200 (herein it refers to the exemplary embodiment of FIGS. 2A and 2B, practically, a number of pad structures to be added depends on a circuitry design of the printed circuit board), such that layout spaces for other components/circuits on the printed circuit board 200 is definitely being restricted. As a result, a layout of the overall circuitry design for the printed circuit board 200 is subject to certain degree of restriction.

FIG. 3A is a schematic diagram illustrating a printed circuit board and a layout structure thereof according to an exemplary embodiment. FIG. 3B is a schematic diagram of an equivalent circuit of the printed circuit board depicted in FIG. 3A. Referring to FIGS. 3A and 3B together, a printed circuit board 300 includes a first circuit CKT1, a second circuit CKT2, pad structures 310 and 320, and electronic components 10_1 and 10_2. Therein, the printed circuit board 300 can also be used in any type of electronic device, and the electronic components 10_1 and 10_2 are also, for example, capacitors.

In the present embodiment, functions of the first circuit CKT1 and the second circuit CKT2 are as described above, this related description are omitted hereinafter. A difference between the printed circuit board 300 and the printed circuit board 200 depicted in FIGS. 2A and 2A is that, the printed circuit board 300 uses the pad structure 100 (refers to the pad structure 310) depicted in FIG. 1. More specifically, in the printed circuit board 300, a terminal of the electronic component 10_1 is coupled to the first circuit CKT1 and the second circuit CKT2 through the pad structure 310, and another terminal of the electronic component 10_1 is coupled to a ground voltage GND. A terminal of the electronic component 10_2 is coupled to the first circuit CKT1 through the conventional pad structure 320, and another terminal of the electronic component 10_2 is coupled to the ground voltage GND. A pad P311_2 (also refers to third pad) is coupled to the first circuit CKT1, and a pad P311_1 (also refers to fourth pad) is coupled to the second circuit CKT2. When the electronic component 10_1 is disposed on the pad structure 310, the pads P311_1 and P311_2 are electrically connected to each other through the solder junction on the electronic component 10_1. In other words, the pads P311_1 and P311_2 allow one terminal of the electronic component 10_1 to equivalently include two connection nodes N1 and N2 (as shown in FIG. 3B). Therefore, in the present exemplary embodiment, the designer only needs to dispose a wiring from the second circuit CKT2 to the second pad P311_1, so as to couple the second circuit CKT2 to the first circuit CKT1. When the second circuit CKT2 is coupled to the first circuit CKT1, the second circuit CKT2 is enabled to work by using the external power.

In other words, since the pad P311_1 is utilized to establish the connection node N1 additionally at one terminal of the electronic component 10_1, the designer only needs to dispose a wiring from the second circuit CKT2 to the pad P311_1, so as to couple the second circuit CKT2 to the first circuit CKT1. Therefore, in comparison with the printed circuit board 200 using the conventional pad structure, the printed circuit board 300 of the present exemplary embodiment, even in the implementation with the second circuit CKT2, does not need to add the electronic component 10_3, the pad structure 230 and the corresponding wiring, as the connection path between the first circuit CKT1 and the second circuit CKT2.

Furthermore, in the present embodiment, it is not required to add electronic components as the connection path for different implementations. Accordingly, the printed circuit board 300 can be realized with the same layout structure regardless of whether it is in the implementations with or without the second circuit CKT2, so as to improve a commonality for designing the printed circuit board.

Besides, a number of the solder junctions of the electronic component 10_1 is identical to a number of the solder junctions of the electronic component 10_2 (both the numbers are 2). A sum of layout areas of the pads P311_1 and P311_2 is similar to that of a pad P312 (slightly smaller than the pad P312), and a layout area of the pad 312 is similar or identical to that of pads P321 or P322 in the pad structure 320. Accordingly, a layout area of the pad structure 310 is substantially identical to a layout area of the pad structure 320. Therefore, in the implementation with the second circuit CKT2, a layout density of the printed circuit board 300 using the pad structure 310 is obviously less than a layout density of the printed circuit board 200 (since it does not include a layout area of pad structure 230). In other words, in the printed circuit board 300 using the pad structure 310, a layout area of the overall circuitry design is substantially reduced, so as to improve a flexibility for the circuit layout design.

It should be noted that, the layout structure of the printed circuit board 300 depicted in FIGS. 3A and 3B is merely an example, and an actual layout structure of the printed circuit board 300 is depended on the corresponding circuitry design, and the invention is not limited thereto. In other words, it does not depart from the scope of the printed circuit board and the layout structure in the invention for which protection is sought, as along as the printed circuit board and the layout structure use the pad structure (e.g., the pad structures 100 or 310) of the present exemplary embodiment. In an exemplary embodiment, the pad structures 100 or 310 can be used in a memory storage device, and the memory storage device can be used together with a host system.

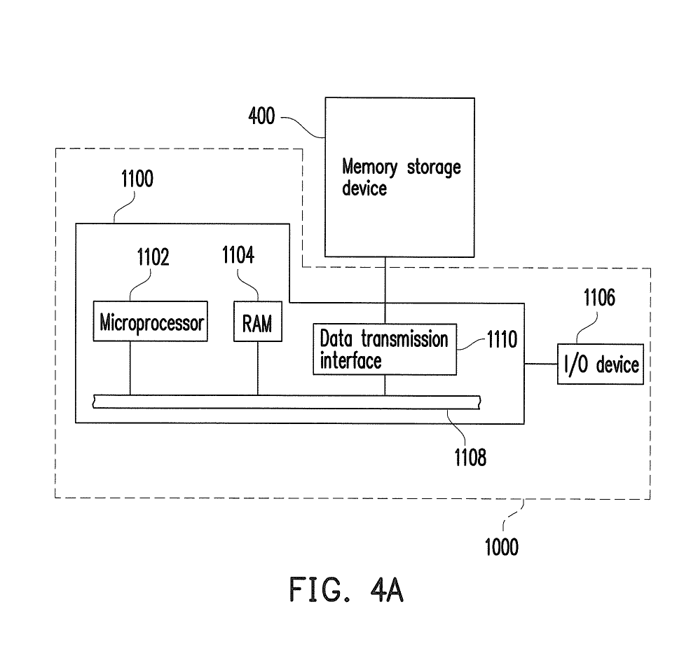

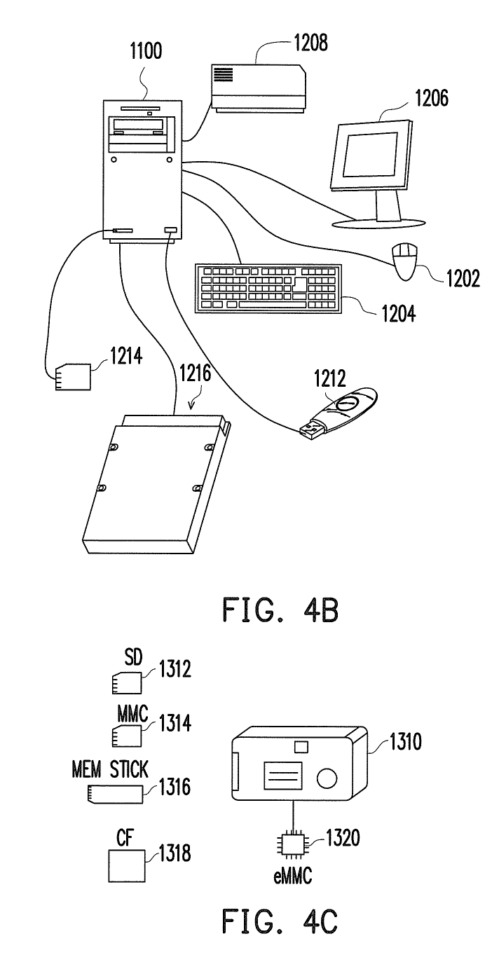

FIG. 4A illustrates a host system and a memory storage device according to an exemplary embodiment.

Referring to FIG. 4A, a host system 1000 includes a computer 1100 and an input/output (I/O) device 1106. The computer 1100 includes a microprocessor 1102, a random access memory (RAM) 1104, a system bus 1108, and a data transmission interface 1110. The 110 device 1106 includes a mouse 1202, a keyboard 1204, a display 1206 and a printer 1208 as shown in FIG. 4B. It should be understood that the devices illustrated in FIG. 4B are not intended to limit the I/O device 1106, and the I/O device 1106 may further include other devices.

The memory storage device 400 is coupled to other devices of the host system 1000 through the data transmission interface 1110. By using the microprocessor 1102, the random access memory (RAM) 1104 and the Input/Output (I/O) device 1106, data may be written to the memory storage device 400 or may be read from the memory storage device 400. For example, the memory storage device 400 may be a rewritable non-volatile memory storage device such as a flash drive 1212, a memory card 1214, or a solid state drive (SSD) 1216 as shown in FIG. 4B.

Generally, the host system 1000 may substantially be any system capable of storing data with the memory storage device 100. Although the host system 1000 is described as a computer system in the present exemplary embodiment, in another exemplary embodiment of the invention, the host system 1000 may be a digital camera, a video camera, a telecommunication device, an audio player, or a video player. For example, if the host system is a digital camera (video camera) 1310, the rewritable non-volatile memory storage device may be a SD card 1312, a MMC card 1314, a memory stick 1316, a CF card 1318 or an embedded storage device 1320 (as shown in FIG. 4). The embedded storage device 1320 includes an embedded MMC (eMMC). It should be mentioned that the eMMC is directly coupled to a substrate of the host system.

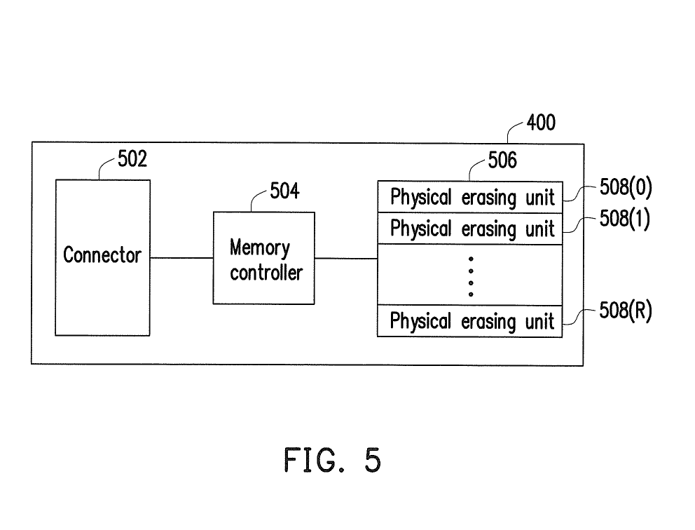

FIG. 5 is a schematic block diagram of the memory storage device depicted in FIG. 4A.

Referring to FIG. 5, the memory storage device 400 includes a connector 502, a memory controller 504 and a rewritable non-volatile memory storage module 506.

In the present exemplary embodiment, the connector 502 is compatible with a serial advanced technology attachment (SATA) standard. However, the invention is not limited thereto, and the connector 502 may also be compatible with a Parallel Advanced Technology Attachment (PATA) standard, an Institute of Electrical and Electronic Engineers (IEEE) 1394 standard, a peripheral component interconnect (PCI) Express interface standard, a universal serial bus (USB) standard, a secure digital (SD) interface standard, a Ultra High Speed-I (UHS-I) interface standard, a Ultra High Speed-II (UHS-II) interface standard, a memory sick (MS) interface standard, a multi media card (MMC) interface standard, an embedded MMC (eMMC) interface standard, a Universal Flash Storage (UFS) interface standard, a compact flash (CF) interface standard, an integrated device electronics (IDE) interface standard or other suitable standards.

The memory controller 504 is configured to execute a plurality of logic gates or control commands which are implemented in a hardware form or in a firmware form, so as to perform operations of writing, reading or erasing data in the rewritable non-volatile memory storage module 506 according to the commands of the host 1000.

The rewritable non-volatile memory storage module 506 is coupled to the memory controller 504 and configured to store data written from the host system 1000. The rewritable non-volatile memory storage module 506 includes multiple physical erasing units 508(0) to 508(R). For example, the physical erasing units 508(0) to 508(R) may belong to the same memory die or belong to different memory dies. Each physical erasing unit has a plurality of physical programming units, and the physical programming units of the same physical erasing unit may be written separately and erased simultaneously. For example, each physical erasing unit is composed by 128 physical programming units. Nevertheless, it should be understood that the invention is not limited thereto. Each physical erasing unit could be composed by 64 physical programming units, 256 physical programming units or any amount of the physical programming units.

More specifically, the physical erasing unit is the minimum unit for erasing. Namely, each physical erasing unit contains the least number of memory cells to be erased together. The physical programming unit is the minimum unit for programming. That is, the physical programming unit is the minimum unit for writing data. Each physical programming unit usually includes a data bit area and a redundancy bit area. The data bit area having multiple physical access address is used to store user data, and the redundant bit area is used to store system data (for example, control information and error checking and correcting code). In the present exemplary embodiment, each data bit area of the physical programming unit contains 4 physical access addresses, and the size of each physical access address is 512-byte (B). However, in other exemplary embodiments, the data bit area may also include 8, 16, or more or less of the physical address, and amount and sizes of the physical access address are not limited in the invention. For example, the physical erasing unit is a physical block, and the physical programming unit is a physical page or a physical sector.

In the present exemplary embodiment, a rewritable non-volatile memory module 506 is a Multi Level Cell (MLC) NAND flash memory module which stores at least 2 bits of data in one cell. The rewritable non-volatile memory module 506 may also be a Single Level Cell (SLC) NAND flash memory module, a Trinary Level Cell (TLC) NAND flash memory module, other flash memory modules or any memory module having the same features.

In the exemplary embodiment of FIG. 5, the connector 502 and the memory controller 504 are disposed on the same printed circuit board, and such printed circuit board includes said pad structures 100 or 310. However, in another exemplary embodiment, the connector 502 and the memory controller 504 can also be disposed on different printed circuit boards, and one of the printed circuit boards includes said pad structures 100 or 310.

In summary, in the exemplary embodiments of the invention, a pad structure, and a printed circuit board and a memory storage device using the same are provided. The pad structure includes at least two pads configured for coupling to the same terminal of the electronic component, so as to establish an additional connection node for the electronic component. Accordingly, the designer can directly utilize the additional connection node to connect two different circuits, so as to reduce the layout area of the circuitry design for the printed circuit board, and improve commonality and flexibility for the circuit layout design.

The previously described exemplary embodiments of the present invention have the advantages aforementioned, wherein the advantages aforementioned not required in all versions of the invention.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A pad structure adapted for disposing an electronic component on a printed circuit board, and the pad structure comprising:
a first pad, configured to couple to a terminal of the electronic component; and
a plurality of second pads, wherein each of the second pads is configured to couple to another terminal of the electronic component, the first pad and the second pads are electrically independent to each other, and the second pads are electrically independent to each other.

2. The pad structure of claim 1, wherein the second pads are disposed at a side of the pad structure, and the first pad is disposed at another side of the pad structure and opposite to the second pads.

3. The pad structure of claim 1, wherein the electronic component is a surface mounting device including a plurality of solder junctions, and the solder junctions including:
a first solder junction, disposed at the terminal of the electronic component; and
a second solder junction, disposed at the another terminal of the electronic component,
wherein the first pad is configured to couple to the terminal of the electronic component through the first solder junction, and the second pads are configured to couple to the another terminal of the electronic component through the second solder junction.

4. The pad structure of claim 3, wherein the second pads comprise:
a third pad, coupled to a first circuit; and
a fourth pad, coupled to a second circuit, wherein the first circuit and the second circuit are electrically independent to each other;
wherein if the electronic component is disposed in the pad structure, the third pad and the fourth pad are electrically connected to each other through the second solder junction, so that the first circuit and the second circuit are electrically connected to each other so as to enable the second circuit.

5. A printed circuit board, comprising:
a first pad structure, wherein the first pad structure comprises:
a first pad configured to coupling to a terminal of an electronic component; and
a plurality of second pads, wherein each of the second pads is configured to couple to another terminal of the electronic component, the first pad and the second pads are electrically independent to each other, and the second pads are electrically independent to each other.

6. The printed circuit board of claim 5, wherein the second pads are disposed at a side of the first pad structure, and the first pad is disposed at another side of the first pad structure and opposite to the second pads.

7. The printed circuit board of claim 5, wherein the electronic component is a surface mounting device including a plurality of solder junctions, and the solder junctions at least including:
a first solder junction, disposed at the terminal of the electronic component; and
a second solder junction, disposed at the another terminal of the electronic component,
wherein the first pad is configured to couple to the terminal of the electronic component through the first solder junction, and the second pads are configured to couple to the another terminal of the electronic component through the second solder junction.

8. The printed circuit board of claim 7, wherein the second pads comprise:
a third pad, coupled to a first circuit; and
a fourth pad, coupled to a second circuit, wherein the first circuit and the second circuit are electrically independent to each other,
wherein if the electronic component is disposed in the pad structure, the third pad and the fourth pad are electrically connected to each other through the second solder junction, so that the first circuit and the second circuit are electrically connected to each other so as to enable the second circuit.

9. The printed circuit board of claim 5, further comprising:
the electronic component, disposed in the first pad structure, wherein the terminal of the electronic component is connected to the first pad, and the another terminal of the electronic component is connected to the second pads.

10. The printed circuit board of claim 5, further comprising:
a second pad structure, wherein the second pad structure comprises:
two fifth pads, wherein one of the two fifth pads is configured to couple to a terminal of a first electronic component, another of the two fifth pads is configured to couple to another terminal of the first electronic component, the two fifth pads are electrically independent to each other, and a number of solder junctions of the first electronic component is identical to a number of the solder junctions of the electronic component.

11. The printed circuit board of claim 10, wherein a layout area of the first pad structure is substantially identical to a layout area of the second pad structure.

12. A memory storage device, comprising:
a connector, configured to couple to a host system;
a rewritable non-volatile memory module including a plurality of physical erasing units.
a memory controller coupled to the connector and the rewritable non-volatile memory,
wherein the connector or the memory controller is disposed on a printed circuit board, and the printed circuit board comprises:
a first pad structure, wherein the first pad structure comprises:
a first pad configured to couple to a terminal of an electronic component; and
a plurality of second pads, wherein each of the second pads is configured to coupling to another terminal of the electronic component,
wherein the first pad and the second pads are electrically independent to each other, and the second pads are electrically independent to each other.

13. The memory storage device of claim 12, wherein the second pads are disposed at a side of the first pad structure, and the first pad is disposed at another side of the first pad structure and opposite to the second pads.

14. The memory storage device of claim 12, wherein the electronic component is a surface mounting device including a plurality of solder junctions, and the solder junctions including:
a first solder junction, disposed at the terminal of the electronic component; and
a second solder junction, disposed at the another terminal of the electronic component,
wherein the first pad is configured to couple to the terminal of the electronic component through the first solder junction, and the second pads are configured to couple to the another terminal of the electronic component through the second solder junction.

15. The memory storage device of claim 14, wherein the second pads comprise:
a third pad, coupled to a first circuit; and
a fourth pad, coupled to a second circuit, wherein the first circuit and the second circuit are electrically independent to each other,
wherein if the electronic component is disposed in the pad structure, the third pad and the fourth pad are electrically connected to each other through the second solder junction, so that the first circuit and the second circuit are electrically connected to each other so as to enable the second circuit.

16. The memory storage device of claim 12, wherein the printed circuit board further comprises:
the electronic component, disposed in the first pad structure, wherein the terminal of the electronic component is connected to the first pad, and the another terminal of the electronic component is connected to the second pads.

17. The memory storage device of claim 12, wherein the printed circuit board further comprises:
a second pad structure, wherein the second pad structure comprises:
two fifth pads, wherein one of the two fifth pads is configured to couple to a terminal of a first electronic component, another of the two fifth pads is configured to couple to another terminal of the first electronic component, the two fifth pads are electrically independent to each other, and a number of solder junctions of the first electronic component is identical to a number of the solder junctions of the electronic component.

18. The memory storage device of claim 17, wherein a layout area of the first pad structure is substantially identical to a layout area of the second pad structure.
